(19) United States
(12) Patent Application Publication
(10) Pub. No.: US 2024/0014109 A1
(43) Pub. Date: Jan. 11, 2024

(54) SEMICONDUCTOR INTERPOSER STRUCTURE

(71) Applicant: NANYA TECHNOLOGY CORPORATION, NEW TAIPEI CITY (TW)

(72) Inventor: CHIN-LING HUANG, TAOYUAN CITY (TW)

(21) Appl. No.: 17/857,220

(22) Filed: Jul. 5, 2022

(51) Int. Cl. H01L 23/498

(52) U.S. Cl. CPC H01L 23/49805; H01L 23/49822; H01L 23/49838

(57) ABSTRACT

A semiconductor device is provided. The semiconductor device includes a body and an interconnection structure. The body has a first lateral surface and a second lateral surface angled relative to the first lateral surface. The interconnection structure is configured to make electrical connection between the semiconductor device and a first electronic component mounted to the first lateral surface of the body of the semiconductor device and to make electrical connection between the semiconductor device and a second electronic component mounted to the second lateral surface of the body of the semiconductor device.

### TECHNICAL FIELD

The present disclosure relates to a semiconductor interposer structure, and more particularly, to a semiconductor interposer structure having an electrical contact at its lateral side.

### DISCUSSION OF THE BACKGROUND

To address a trend towards smaller sizes, a semiconductor package should effectively utilize its package size such that the component could be packaged as many as possible. An interposer is used as an interconnection between two electronic components, such as substrates and/or dies.

The interposer is usually arranged between two electronic components and used to electrically connect the two electronic components to each other. For example, two electronic components are arranged at the top and the bottom of the interposer and electrically connected to the interposer. No electronic component could be arranged at the lateral side of the interposer and electrically connected to the interposer.

### SUMMARY

One aspect of the present disclosure provides a semiconductor device. The semiconductor device includes a body and an interconnection structure. The body has a first lateral surface and a second lateral surface connected to the first lateral surface at an angle. The interconnection structure is configured to make electrical connection between the semiconductor device and a first electronic component mounted to the first lateral surface of the body of the semiconductor device and to make electrical connection between the semiconductor device and a second electronic component mounted to the second lateral surface of the body of the semiconductor device.

Another aspect of the present disclosure provides a semiconductor device. The semiconductor device includes a body, an interconnection structure, a plurality of first electrical contacts, a plurality of second electrical contacts and a plurality of third electrical contacts. The body has a bottom surface, a first surface and a second surface. The interconnection structure is formed a part of the body. The first electrical contacts are arranged on the bottom surface of the body and electrically connected to the interconnection structure. The second electrical contacts are arranged on the first surface of the body and electrically connected to the interconnection structure. The third electrical contacts are arranged on the second surface of the body and electrically connected to the interconnection structure.

Another aspect of the present disclosure provides a semiconductor interposer device. The semiconductor interposer device includes a first circuit layer and a second circuit layer. The first circuit layer has a plurality of first electrical contact on a first lateral surface of the semiconductor interposer device and a plurality of second electrical contacts on a second lateral surface of the semiconductor interposer device. The second circuit layer has a plurality of third electrical contacts on the first lateral surface of the semiconductor interposer device and a plurality of fourth electrical contacts on a third lateral surface of the semiconductor interposer device. The first electrical contact and the second electrical contact are electrically connected to each other and the third electrical contact and the fourth electrical contact are electrically connected to each other.

In some embodiments, the body comprises a substantially cuboid body.

In some embodiments, the first circuit layer is attached to the second circuit layer.

In some embodiments, a normal of the first lateral surface is substantially perpendicular to a normal of the second lateral surface, and wherein the third lateral surface is opposite to the second lateral surface.

In some embodiments, a normal of the first lateral surface is substantially perpendicular to a normal of the second lateral surface, and wherein the third lateral surface is opposite to the first lateral surface.

In some embodiments, the semiconductor interposer device further comprises a third circuit layer, wherein the third circuit layer has a plurality of fifth electrical contacts at the first lateral surface of the semiconductor interposer device and a plurality of sixth electrical contacts at a fourth lateral surface of the semiconductor interposer device, and wherein the fifth electrical contact and the sixth electrical contact are electrically connected to each other, and wherein the first lateral surface is opposite to the fourth lateral surface, and wherein the second lateral surface is opposite to the third lateral surface.

In some embodiments, the third circuit layer is attached to the first circuit layer or the second circuit layer.

In some embodiments, the second circuit layer has a plurality of seventh electrical contact at a fifth lateral surface of the semiconductor device, and wherein the seventh electrical contact and the fourth electrical contact are electrically connected to each other.

In some embodiments, the first lateral surface is opposite to the third lateral surface, and wherein the second lateral surface is opposite to the fifth lateral surface.

In some embodiments, wherein an electronic component is mounted to the first lateral surface, the second lateral surface or the third lateral surface of the semiconductor interposer device and electrically connected to the semiconductor interposer device.

In the semiconductor interposer device, with the design of the interconnection structure and the electrical contact at the lateral side of the semiconductor interposer device can make electrical connection between the semiconductor interposer device and an electronic component mounted on the lateral side of the semiconductor interposer device.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a schematic perspective view of a semiconductor device, in accordance with some embodiments of the present disclosure.

FIG. 2 is a schematic side view of a semiconductor device, in accordance with some embodiments of the present disclosure.

FIG. 3 is a schematic top view of a semiconductor device, in accordance with some embodiments of the present disclosure.

FIG. 4A illustrates a schematic cross-sectional view along line A1-A1 in FIG. 3.

FIG. 4B illustrates a schematic cross-sectional view along line B1-B1 in FIG. 3.

FIG. 4C illustrates a schematic cross-sectional view along line C1-C1 in FIG. 3.

FIG. 5 is a schematic view of a semiconductor device assembly, in accordance with some embodiments of the present disclosure.

FIG. 6 is a schematic perspective view of a semiconductor device, in accordance with some embodiments of the present disclosure . . . .

FIG. 7 is a schematic side view of a semiconductor device, in accordance with some embodiments of the present disclosure.

FIG. 8 is a schematic top view of a semiconductor device, in accordance with some embodiments of the present disclosure.

FIG. 9A illustrates a schematic cross-sectional view along line A2-A2 in FIG. 8.

FIG. 9B illustrates a schematic cross-sectional view along line B2-B2 in FIG. 8.

FIG. 9C illustrates a schematic cross-sectional view along line C2-C2 in FIG. 8.

FIG. 10 is a schematic view of a semiconductor device assembly, in accordance with some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

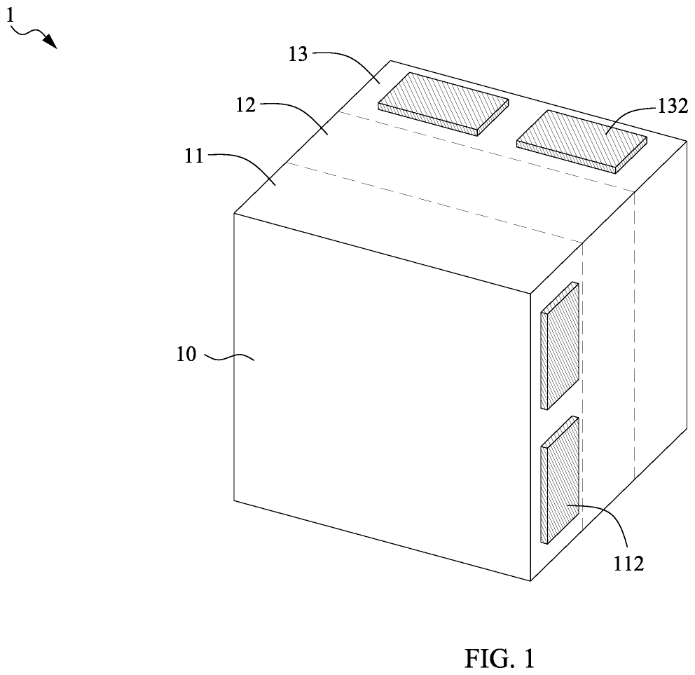

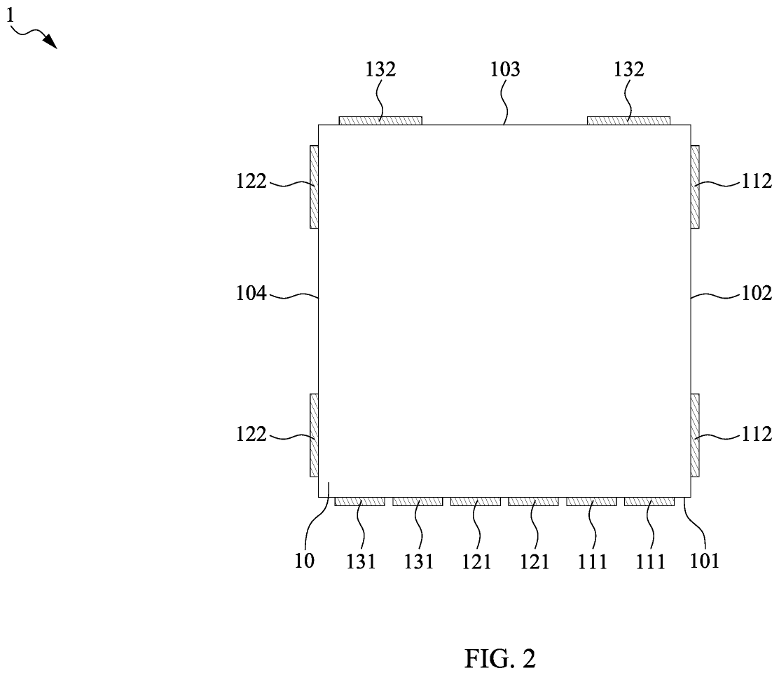

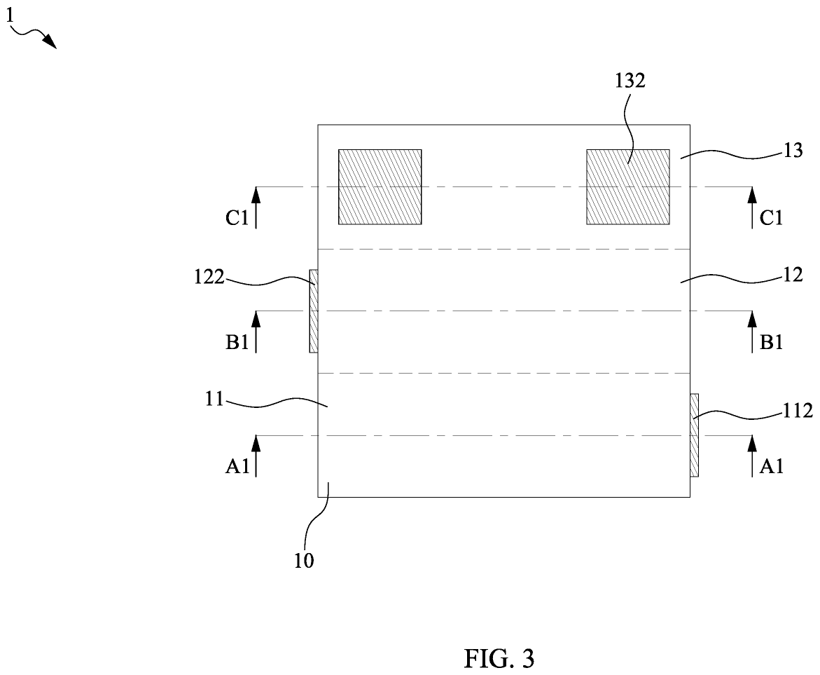

FIG. 1 is a schematic perspective view of a semiconductor device 1 according to an embodiment. FIG. 2 is a schematic side view of a semiconductor device 1 according to an embodiment. FIG. 3 is a schematic top view of a semiconductor device 1 according to an embodiment. In some embodiments of the present disclosure, the semiconductor device 1 includes a semiconductor interposer structure.

Referring to FIG. 1, FIG. 2 and FIG. 3 together, the semiconductor device 1 may include a main body 10. In some embodiments of the present disclosure, the main body 10 has a substantially cuboid body. The main body 10 may include circuit layers 11, 12 and 13. In some embodiments of the present disclosure, the circuit layer 11 is attached to the circuit layer 12, and the circuit layer 12 is attached to the circuit layer 13.

As shown in FIG. 2, the main body 10 may have a surface 101 (e.g., a lower surface), a surface 102 (e.g., a lateral surface), a surface 103 (e.g., an upper surface) opposite to the surface 101 and a surface 104 (e.g., a lateral surface) opposite to the surface 102. In some embodiments, the surface 102 is connected to the surface 101 at an angle of about 90 degrees. That is, a normal of the surface 102 may be substantially perpendicular to a normal of the surface 101. In some embodiments of the present disclosure, the surface 104 is connected to the surface 101 at an angle of about 90 degrees. That is, a normal of the surface 104 may be substantially perpendicular to a normal of the surface 101. In some embodiments of the surface 103 is substantially parallel to the surface 101.

Further, the semiconductor device 1 may include electrical contacts 111, 121, 131 in proximity to, adjacent to, or embedded in and exposed by the surface 101 of the main body 10, electrical contacts 112 on the surface 102 of the main body 10, electrical contacts 132 in proximity to, adjacent to, or embedded in and exposed by the surface 103 of the main body 10 and electrical contacts 122 in proximity to, adjacent to, or embedded in and exposed by the surface 104. In some embodiments of the present disclosure, the electrical contact 111, 112, 121, 122, 131, 132 may include a conductive pad.

When an electronic component is disposed on or mounted to the surface 101 of the main body 10, the electronic component may be electrically connected to the semiconductor device 1 through the electrical contacts 111, 121 and/or 131. When an electronic component is disposed on or mounted to the surface 102 of the main body 10, the electronic component may be electrically connected to the semiconductor device 1 through the electrical contacts 112. When an electronic component is disposed on or mounted to the surface 103 of the main body 10, the electronic component may be electrically connected to the semiconductor device 1 through the electrical contacts 132. When an electronic component is disposed on or mounted to the surface 104 of the main body 10, the electronic component may be electrically connected to the semiconductor device 1 through the electrical contacts 122.

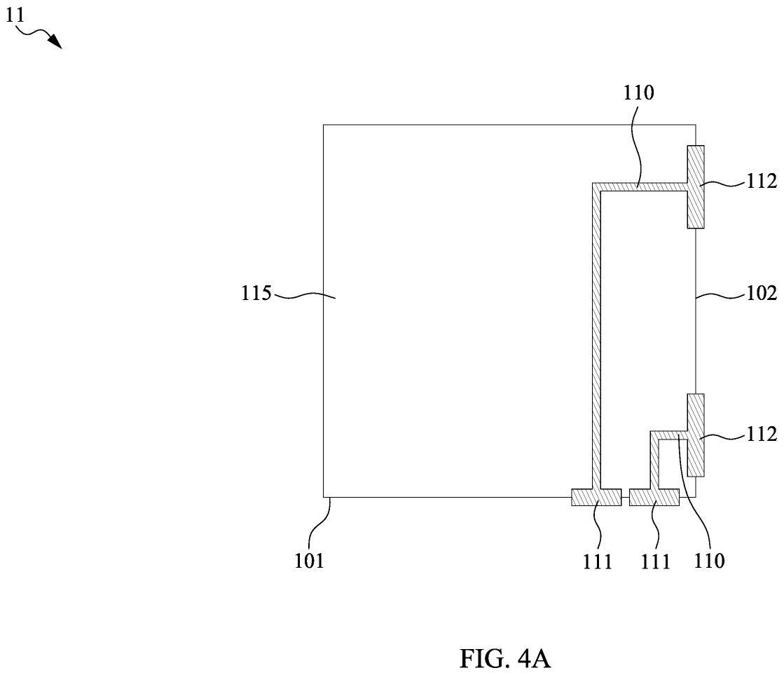

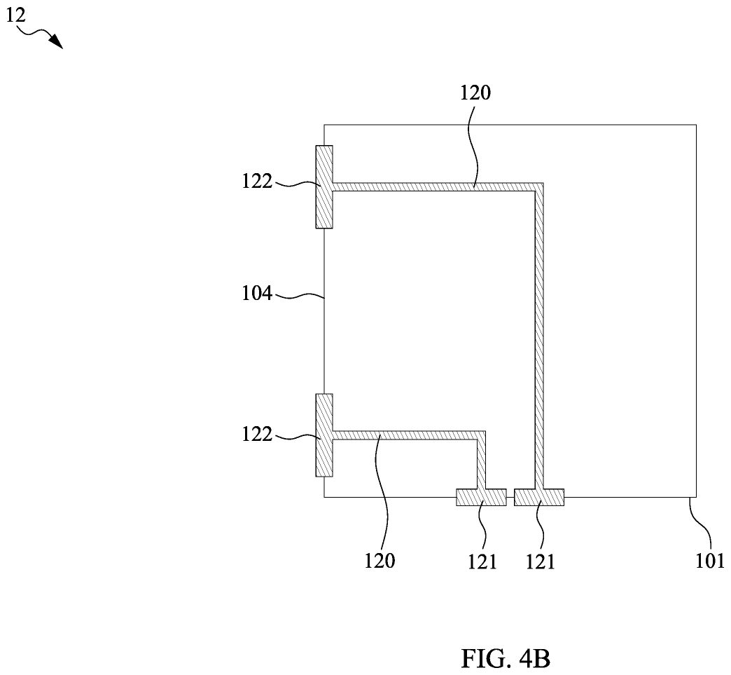

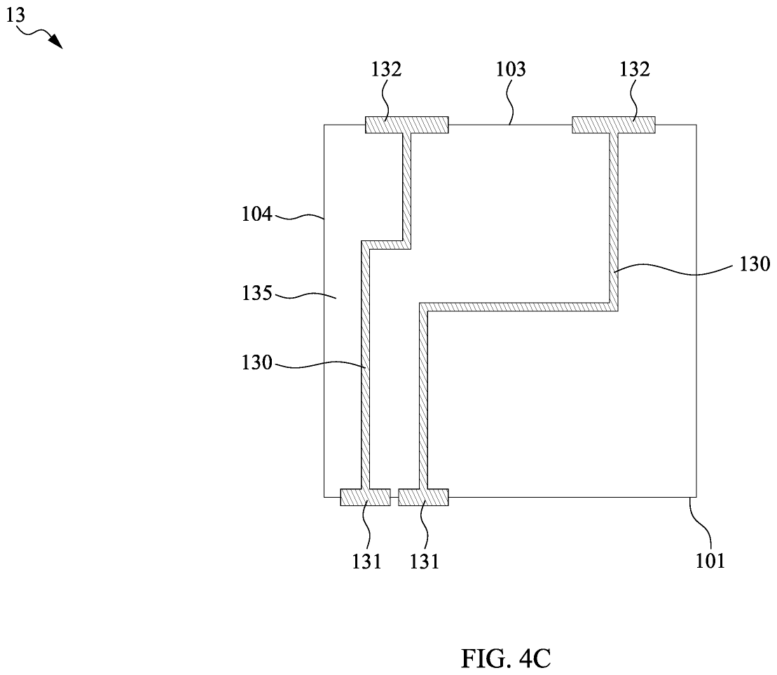

FIG. 4A illustrates a schematic cross-sectional view along line A1-A1 in FIG. 3. In some embodiments of the present disclosure, FIG. 4A shows a cross-section of the circuit layer 11. As shown in FIG. 4A, the circuit layer 11 may include one or more interconnection layers (e.g., redistribution layer, RDL) 110 and one or more dielectric layers 115. The interconnection layer 110 may be connected to the electrical contacts 111 adjacent to the surface 101 of the main body 10 and the electrical contacts 112 adjacent to the surface 102 of the main body 10. That is, the electrical contacts 111 and 112 may be parts of the circuit layer 11. Thus, when an electronic component is disposed on the surface 101 of the main body 10 and connected to the electrical contacts 111, the electronic component may be electrically connected to the interconnection layer 110. Likewise, when an electronic component is disposed on the surface 102 of the main body 10 and connected to the electrical contacts 112, the electronic component may be electrically connected to the interconnection layer 110. Further, the interconnection layer 110 may be configured to electrically connect the electrical contact 111 to the electrical contact 112. That is, the electronic component disposed on the surface 101 of the main body 10 and connected to the electrical contact 111 and the electronic component disposed on the surface 102 of the main body 10 and connected to the electrical contact 112 may be electrically connected to each other via the interconnection layer 110.

FIG. 4B illustrates a schematic cross-sectional view along line B1-B1 in FIG. 3. In some embodiments of the present disclosure, FIG. 4B shows a cross-section of the circuit layer 12. As shown in FIG. 4B, the circuit layer 12 may include one or more interconnection layers (e.g., redistribution layer, RDL) 120 and one or more dielectric layers 125. The interconnection layer 120 may be connected to the electrical contacts 121 adjacent to the surface 101 of the main body 10 and the electrical contacts 122 adjacent to the surface 104 of the main body 10. That is, the electrical contacts 121 and 122 may be parts of the circuit layer 12. Thus, when an electronic component is disposed on the surface 101 of the main body 10 and connected to the electrical contacts 121, the electronic component may be electrically connected to the interconnection layer 120. Likewise, when an electronic component is disposed on the surface 104 of the main body 10 and connected to the electrical contacts 122, the electronic component may be electrically connected to the interconnection layer 120. Further, the interconnection layer 120 may be configured to electrically connect the electrical contact 121 to the electrical contact 122. That is, the electronic component disposed on the surface 101 of the main body 10 and connected to the electrical contact 121 and the electronic component disposed on the surface 104 of the main body 10 and connected to the electrical contact 122 may be electrically connected to each other via the interconnection layer 120.

FIG. 4C illustrates a schematic cross-sectional view along line C1-C1 in FIG. 3. In some embodiments of the present disclosure, FIG. 4C shows a cross-section of the circuit layer 13. As shown in FIG. 4C, the circuit layer 13 may include one or more interconnection layers (e.g., redistribution layer, RDL) 130 and one or more dielectric layers 135. The interconnection layer 130 may be connected to the electrical contacts 131 adjacent to the surface 101 of the main body 10 and the electrical contacts 132 adjacent the surface 103 of the main body 10. That is, the electrical contacts 131 and 132 may be parts of the circuit layer 13. Thus, when an electronic component is disposed on the surface 101 of the main body 10 and connected to the electrical contacts 131, the electronic component may be electrically connected to the interconnection layer 130. Likewise, when an electronic component is disposed on the surface 103 of the main body 10 and connected to the electrical contacts 132, the electronic component may be electrically connected to the interconnection layer 130. Further, the interconnection layer 130 may be configured to electrically connect the electrical contact 131 to the electrical contact 132. That is, the electronic component disposed on the surface 101 of the main body 10 and connected to the electrical contact 131 and the electronic component disposed on the surface 103 of the main body 10 and connected to the electrical contact 132 may be electrically connected to each other via the interconnection layer 120.

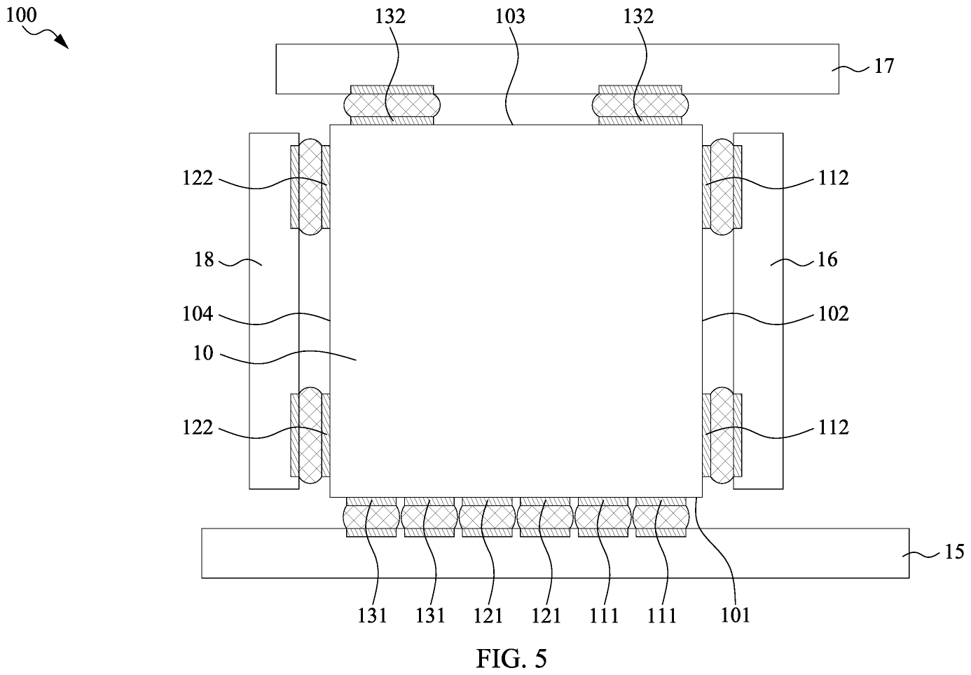

FIG. 5 is a schematic view of a semiconductor device assembly 100, in accordance with some embodiments of the present disclosure. Referring to FIG. 5, the semiconductor device assembly 100 may include the semiconductor device 1, an electronic component 15 disposed on or mounted to the surface 101 of the body 10 of the semiconductor device 1, an electronic component 16 disposed on or mounted to the surface 102 of the main body 10 of the semiconductor device 1, an electronic component 17 disposed on or mounted to the surface 103 of the main body 10 of the semiconductor device 1 and an electronic component 18 disposed on or mounted to the surface 104 of the main body 10 of the semiconductor device 1.

As shown in FIG. 5, the electronic component 15 is disposed on the surface 101 of the main body 10 of the semiconductor device 1. The electronic component 15 may be a die, an active device, a passive device, and/or other electronic devices. Moreover, the electronic component 15 may be a substrate, which may be a core substrate or a core-less substrate and may include traces, pads or interconnections for electrical connection. In some embodiments of the present disclosure, the electronic component 15 is connected to the electrical contacts 111, 121, 131 of the semiconductor device 1 via electrical connections, and thus the electronic component 15 is electrically connected to the semiconductor device 1.

Further, the electronic component 16 is disposed on the surface 102 of the main body 10 of the semiconductor device 1. The electronic component 16 may be a die, an active device, a passive device, and/or other electronic devices. In some embodiments of the present disclosure, the electronic component 16 is connected to the electrical contact 112 of the semiconductor device 1 via electrical connections, and thus the electronic component 16 is electrically connected to the semiconductor device 1.

The electronic component 17 is disposed on the surface 103 of the main body 10 of the semiconductor device 1. The electronic component 17 may be a die, an active device, a passive device, and/or other electronic devices. Moreover, the electronic component 17 may be a substrate, which may be a core substrate or a core-less substrate and may include traces, pads or interconnections for electrical connection. In some embodiments of the present disclosure, the electronic component 17 is connected to the electrical contact 132 of the semiconductor device 1 via electrical connections, and thus the electronic component 17 is electrically connected to the semiconductor device 1.

Further, the electronic component 18 is disposed on the surface 104 of the main body 10 of the semiconductor device 1. The electronic component 18 may be a die, an active device, a passive device, and/or other electronic devices. In some embodiments of the present disclosure, the electronic component 18 is connected to the electrical contact 122 of the semiconductor device 1 via electrical connections, and thus the electronic component 18 is electrically connected to the semiconductor device 1.

As shown in FIG. 4A, the circuit layer 11 may include the interconnection layer 110 which is connected to the electrical contact 111 on the surface 101 and the electrical contact 112 on the surface 102 and configured to electrically connect the electrical contact 111 to the electrical contact 112. Thus, referring to FIG. 4A and FIG. 5 together, the electronic device 15 disposed on the surface 101 and the electronic device 16 disposed on the surface 102 may be electrically connected to the interconnection layer 110 of the circuit layer 11. Further, the interconnection layer 110 may be configured to electrically connect the electronic device 15 to the electronic device 16.

As shown in FIG. 4B, the circuit layer 12 may include the interconnection layer 120 which is connected to the electrical contact 121 on the surface 101 and the electrical contact 122 on the surface 104 and configured to electrically connect the electrical contact 121 to the electrical contact 122. Thus, referring to FIG. 4B and FIG. 5 together, the electronic device 15 disposed on the surface 101 and the electronic device 18 disposed on the surface 104 may be electrically connected to the interconnection layer 120 of the circuit layer 12. Further, the interconnection layer 120 may be configured to electrically connect the electronic device 15 to the electronic device 18.

As shown in FIG. 4C, the circuit layer 13 may include the interconnection layer 130 which is connected to the electrical contact 131 on the surface 101 and the electrical contact 132 on the surface 103 and configured to electrically connect the electrical contact 131 to the electrical contact 132. Thus, referring to FIG. 4C and FIG. 5 together, the electronic device 15 disposed on the surface 101 and the electronic device 17 disposed on the surface 103 may be electrically connected to the interconnection layer 130 of the circuit layer 13. Further, the interconnection layer 130 may be configured to electrically connect the electronic device 15 to the electronic device 17.

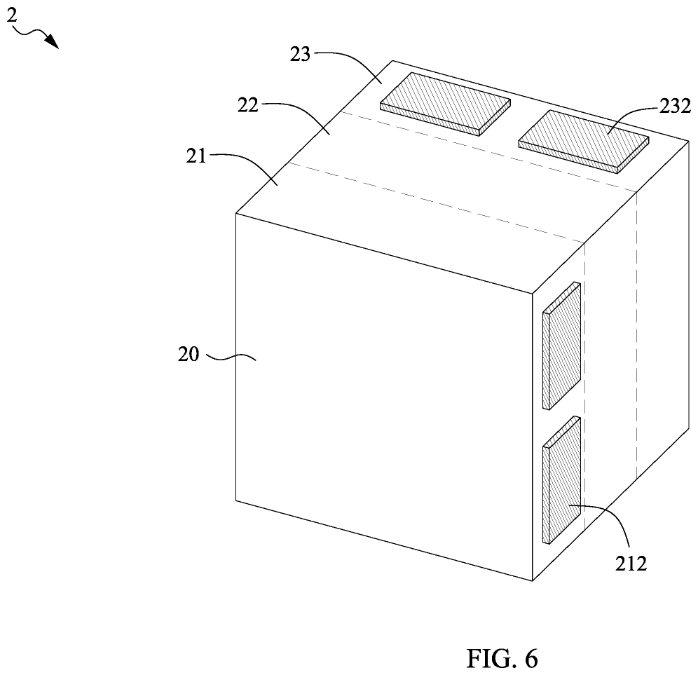

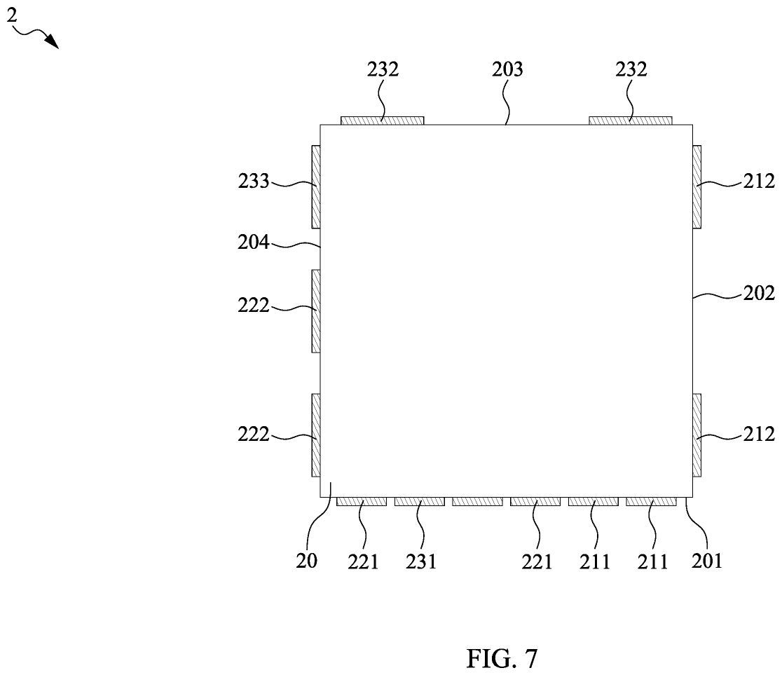

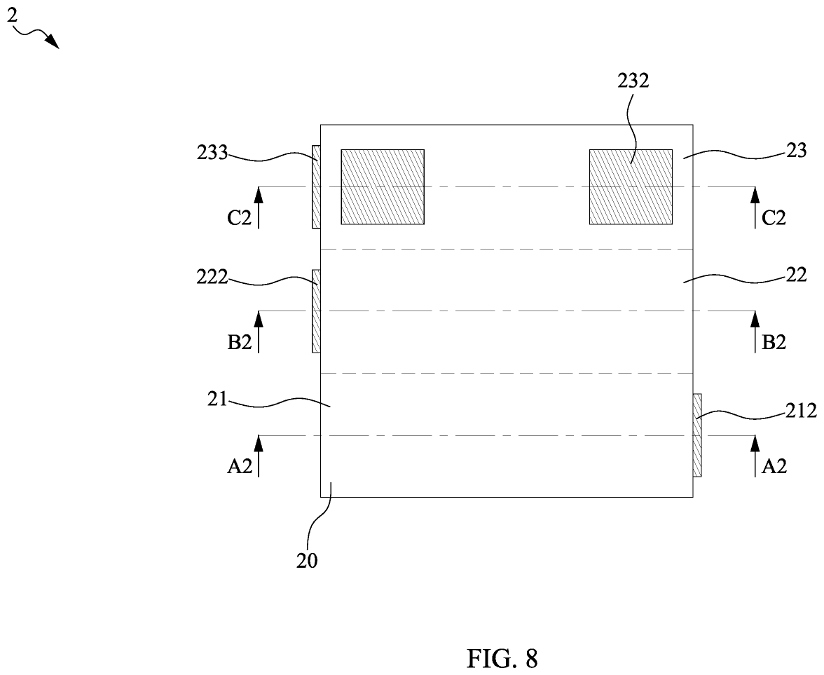

FIG. 6 is a schematic perspective view of a semiconductor device 2 according to an embodiment. FIG. 7 is a schematic side view of a semiconductor device 2 according to an embodiment. FIG. 8 is a schematic top view of a semiconductor device 2 according to an embodiment. In some embodiments of the present disclosure, the semiconductor device 2 includes a semiconductor interposer structure.

Referring to FIG. 6, FIG. 7 and FIG. 8 together, the semiconductor device 2 may include a main body 20. In some embodiments of the present disclosure, the main body 20 has a substantially cuboid body. The main body 20 may include circuit layers 21, 22 and 23. In some embodiments of the present disclosure, the circuit layer 21 is attached to the circuit layer 22, and the circuit layer 22 is attached to the circuit layer 23.

As shown in FIG. 7, the main body 20 may have a surface 201 (e.g., a lower surface), a surface 202 (e.g., a lateral surface), a surface 203 (e.g., an upper surface) opposite to the surface 201 and a surface 204 (e.g., a lateral surface) opposite to the surface 202. In some embodiments, the surface 202 is connected to the surface 201 at an angle of about 90 degrees. That is, a normal of the surface 202 may be substantially perpendicular to a normal of the surface 201. In some embodiments of the present disclosure, the surface 204 is connected to the surface 201 at an angle of about 90 degrees. That is, a normal of the surface 204 may be substantially perpendicular to a normal of the surface 201. In some embodiments of the surface 203 is substantially parallel to the surface 201.

Further, the semiconductor device 2 may include electrical contacts 211, 221, 231 in proximity to, adjacent to, or embedded in and exposed by the surface 201 of the main body 20, electrical contacts 212 in proximity to, adjacent to, or embedded in and exposed by the surface 202 of the main body 20, electrical contacts 232 in proximity to, adjacent to, or embedded in and exposed by the surface 203 of the main body 20 and electrical contacts 222, 233 in proximity to, adjacent to, or embedded in and exposed by the surface 204 of the body 20. In some embodiments of the present disclosure, the electrical contact 211, 212, 221, 222, 231, 232, 233 may include a conductive pad.

When an electronic component is disposed on or mounted to the surface 201 of the main body 20, the electronic component may be electrically connected to the semiconductor device 2 through the electrical contacts 211, 221 and/or 231. When an electronic component is disposed on or mounted to the surface 202 of the main body 20, the electronic component may be electrically connected to the semiconductor device 2 through the electrical contacts 212. When an electronic component is disposed on or mounted to the surface 203 of the main body 20, the electronic component may be electrically connected to the semiconductor device 2 through the electrical contacts 232. When an electronic component is disposed on or mounted to the surface 204 of the main body 20, the electronic component may be electrically connected to the semiconductor device 2 through the electrical contacts 222, 233.

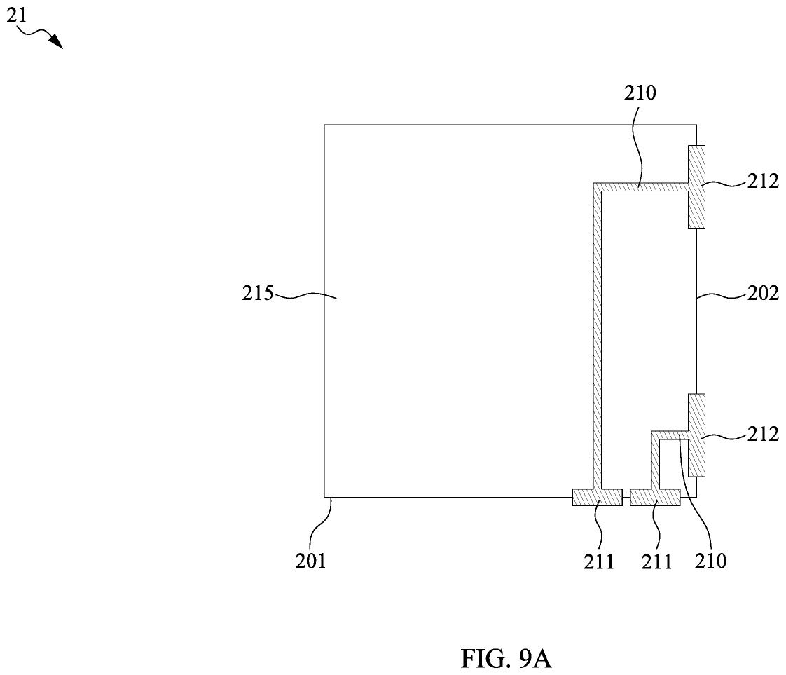

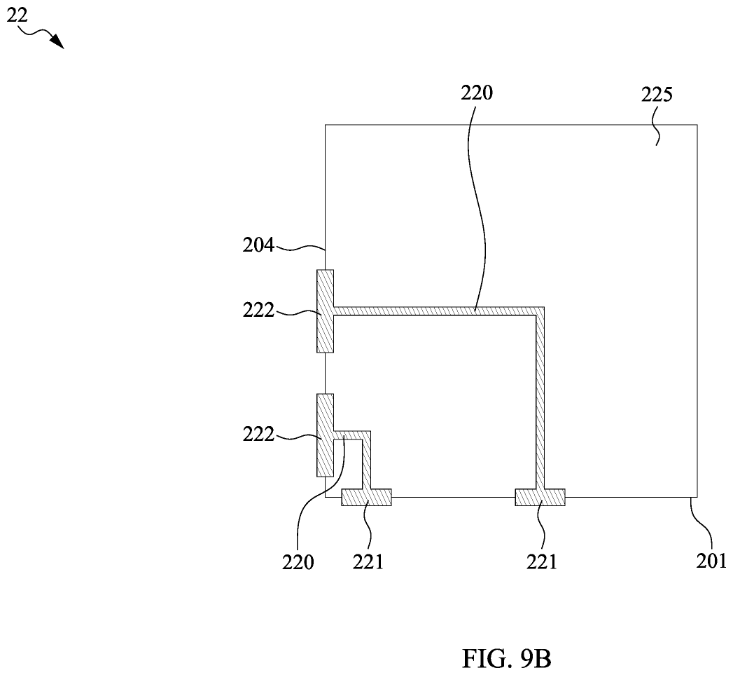

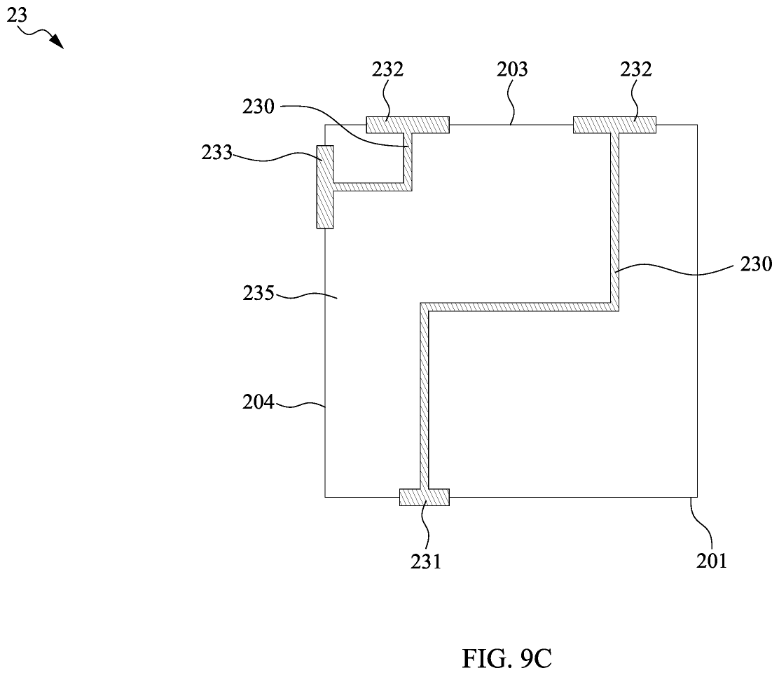

FIG. 9A illustrates a schematic cross-sectional view along line A2-A2 in FIG. 8. In some embodiments of the present disclosure, FIG. 9A shows a cross-section of the circuit layer 21. As shown in FIG. 9A, the circuit layer 21 may include one or more interconnection layers (e.g., redistribution layer, RDL) 210 and one or more dielectric layers 215. The interconnection layer 210 may be connected to the electrical contacts 211 adjacent to the surface 201 of the main body 20 and the electrical contacts 212 adjacent to the surface 202 of the main body 20. That is, the electrical contacts 211 and 212 may be parts of the circuit layer 21. Thus, when an electronic component is disposed on the surface 201 of the main body 20 and connected to the electrical contacts 211, the electronic component may be electrically connected to the interconnection layer 210. Likewise, when an electronic component is disposed on the surface 202 of the main body 20 and connected to the electrical contacts 212, the electronic component may be electrically connected to the interconnection layer 210. Further, the interconnection layer 210 may be configured to electrically connect the electrical contact 211 to the electrical contact 212. That is, the electronic component disposed on the surface 201 of the main body 20 and connected to the electrical contact 211 and the electronic component disposed on the surface 202 of the main body 20 and connected to the electrical contact 212 may be electrically connected to each other via the interconnection layer 210.

FIG. 9B illustrates a schematic cross-sectional view along line B2-B2 in FIG. 8. In some embodiments of the present disclosure, FIG. 9B shows a cross-section of the circuit layer 22. As shown in FIG. 9B, the circuit layer 22 may include one or more interconnection layers (e.g., redistribution layer, RDL) 220 and one or more dielectric layers 225. The interconnection layer 220 may be connected to the electrical contacts 221 adjacent to the surface 201 of the main body 20 and the electrical contacts 222 adjacent to the surface 204 of the main body 20. That is, the electrical contacts 221 and 222 may be parts of the circuit layer 22. Thus, when an electronic component is disposed on the surface 201 of the main body 20 and connected to the electrical contacts 221, the electronic component may be electrically connected to the interconnection layer 220. Likewise, when an electronic component is disposed on the surface 204 of the main body 20 and connected to the electrical contacts 222, the electronic component may be electrically connected to the interconnection layer 220. Further, the interconnection layer 220 may be configured to electrically connect the electrical contact 221 to the electrical contact 222. That is, the electronic component disposed on the surface 201 of the main body 20 and connected to the electrical contact 221 and the electronic component disposed on the surface 204 of the main body 20 and connected to the electrical contact 222 may be electrically connected to each other via the interconnection layer 220.

FIG. 9C illustrates a schematic cross-sectional view along line C2-C2 in FIG. 8. In some embodiments of the present disclosure, FIG. 9C shows a cross-section of the circuit layer 23. As shown in FIG. 4C, the circuit layer 23 may include one or more interconnection layers (e.g., redistribution layer, RDL) 230 and one or more dielectric layers 235. The interconnection layer 230 may be connected to the electrical contact 231 adjacent to the surface 201 of the main body 20 and the electrical contacts 232 adjacent to the surface 203 of the main body 20 and the electrical contact 233 adjacent to the surface 204 of the main body 20. That is, the electrical contacts 231, 232 and 233 may be parts of the circuit layer 23. Thus, when an electronic component is disposed on the surface 201 of the main body 20 and connected to the electrical contact 231, the electronic component may be electrically connected to the interconnection layer 230. Likewise, when an electronic component is disposed on the surface 203 of the main body 20 and connected to the electrical contacts 232, the electronic component may be electrically connected to the interconnection layer 230. When an electronic component is disposed on the surface 204 of the main body 20 and connected to the electrical contacts 233, the electronic component may be electrically connected to the interconnection layer 230. Further, the interconnection layer 230 may be configured to electrically connect the electrical contact 231 to the electrical contact 232. That is, the electronic component disposed on the surface 201 of the main body 20 and connected to the electrical contact 231 and the electronic component disposed on the surface 203 of the main body 20 and connected to the electrical contact 232 may be electrically connected to each other via the interconnection layer 220. Moreover, the interconnection layer 230 may be configured to electrically connect the electrical contact 232 to the electrical contact 233. That is, the electronic component disposed on the surface 203 of the main body 20 and connected to the electrical contact 232 and the electronic component disposed on the surface 204 of the main body 20 and connected to the electrical contact 233 may be electrically connected to each other via the interconnection layer 220.

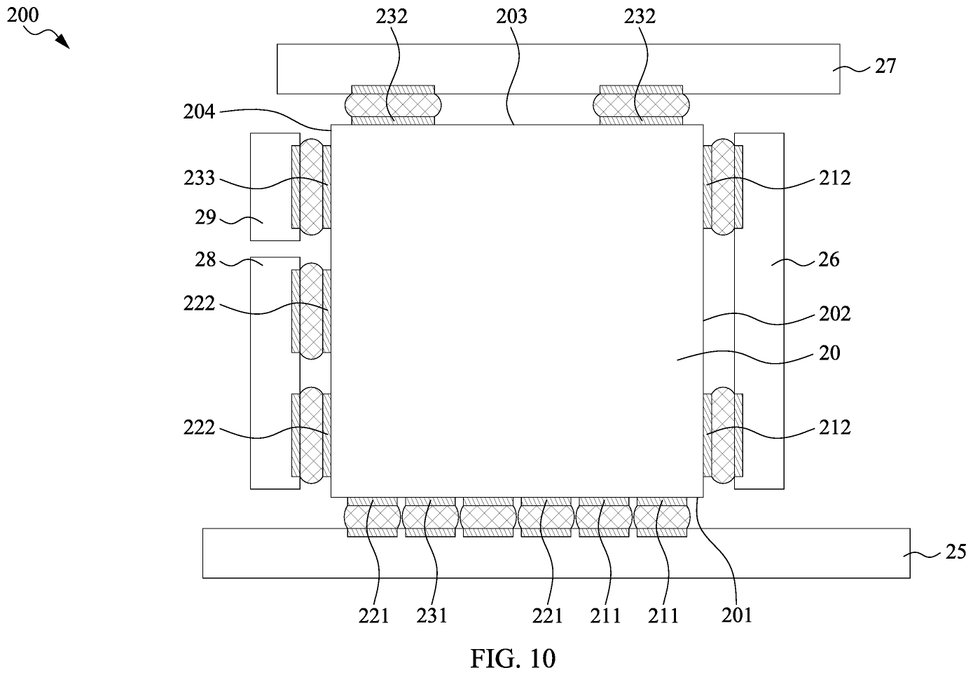

FIG. 10 is a schematic view of a semiconductor device assembly 200, in accordance with some embodiments of the present disclosure. Referring to FIG. 10, the semiconductor device assembly 200 may include the semiconductor device 2, an electronic component 25 disposed on or mounted to the surface 201 of the body 20 of the semiconductor device 2, an electronic component 26 disposed on or mounted to the surface 202 of the main body 20 of the semiconductor device 2, an electronic component 127 disposed on or mounted to the surface 203 of the main body 20 of the semiconductor device 2, an electronic component 28 disposed on or mounted to the surface 204 of the main body 20 of the semiconductor device 2 and an electronic component 29 disposed on or mounted to the surface 204 of the main body 20 of the semiconductor device 2.

As shown in FIG. 10, the electronic component 25 is disposed on the surface 201 of the main body 20 of the semiconductor device 2. The electronic component 25 may be a die, an active device, a passive device, and/or other electronic devices. Moreover, the electronic component 25 may be a substrate, which may be a core substrate or a core-less substrate and may include traces, pads or interconnections for electrical connection. In some embodiments of the present disclosure, the electronic component 25 is connected to the electrical contacts 211, 221, 231 of the semiconductor device 2 via electrical connections, and thus the electronic component 25 is electrically connected to the semiconductor device 2.

Further, the electronic component 26 is disposed on the surface 202 of the main body 20 of the semiconductor device 2. The electronic component 26 may be a die, an active device, a passive device, and/or other electronic devices. In some embodiments of the present disclosure, the electronic component 26 is connected to the electrical contact 212 of the semiconductor device 2 via electrical connections, and thus the electronic component 26 is electrically connected to the semiconductor device 2.

The electronic component 27 is disposed on the surface 203 of the main body 20 of the semiconductor device 2. The electronic component 27 may be a die, an active device, a passive device, and/or other electronic devices. Moreover, the electronic component 27 may be a substrate, which may be a core substrate or a core-less substrate and may include traces, pads or interconnections for electrical connection. In some embodiments of the present disclosure, the electronic component 27 is connected to the electrical contact 232 of the semiconductor device 2 via electrical connections, and thus the electronic component 27 is electrically connected to the semiconductor device 2.

The electronic component 28 is disposed on the surface 204 of the main body 20 of the semiconductor device 2. The electronic component 28 may be a die, an active device, a passive device, and/or other electronic devices. In some embodiments of the present disclosure, the electronic component 28 is connected to the electrical contact 222 of the semiconductor device 2 via electrical connections, and thus the electronic component 28 is electrically connected to the semiconductor device 1.

Further, the electronic component 29 is disposed on the surface 204 of the main body 20 of the semiconductor device 2. The electronic component 29 may be a die, an active device, a passive device, and/or other electronic devices. In some embodiments of the present disclosure, the electronic component 29 is connected to the electrical contact 233 of the semiconductor device 2 via electrical connections, and thus the electronic component 29 is electrically connected to the semiconductor device 1.

As shown in FIG. 9A, the circuit layer 21 may include the interconnection layer 210 which is connected to the electrical contact 211 on the surface 201 and the electrical contact 212 on the surface 202 and configured to electrically connect the electrical contact 211 to the electrical contact 212. Thus, referring to FIG. 9A and FIG. 10 together, the electronic device 25 disposed on the surface 201 and the electronic device 26 disposed on the surface 202 may be electrically connected to the interconnection layer 120 of the circuit layer 21. Further, the interconnection layer 210 may be configured to electrically connect the electronic device 25 to the electronic device 26.

As shown in FIG. 9B, the circuit layer 22 may include the interconnection layer 220 which is connected to the electrical contact 221 on the surface 201 and the electrical contact 222 on the surface 204 and configured to electrically connect the electrical contact 221 to the electrical contact 222. Thus, referring to FIG. 9B and FIG. 10 together, the electronic device 25 disposed on the surface 201 and the electronic device 28 disposed on the surface 204 may be electrically connected to the interconnection layer 220 of the circuit layer 22. Further, the interconnection layer 220 may be configured to electrically connect the electronic device 25 to the electronic device 28.

As shown in FIG. 9C, the circuit layer 23 may include the interconnection layer 230 which is connected to the electrical contact 231 on the surface 201 and the electrical contact 232 on the surface 203 and configured to electrically connect the electrical contact 231 to the electrical contact 232. Thus, referring to FIG. 9C and FIG. 10 together, the electronic device 25 disposed on the surface 201 and the electronic device 27 disposed on the surface 203 may be electrically connected to the interconnection layer 230 of the circuit layer 23. Further, the interconnection layer 230 may be configured to electrically connect the electronic device 25 to the electronic device 27.

Moreover, the interconnection layer 230 may be connected to the electrical contact 233 on the surface 204 and the electrical contact 232 on the surface 203 and configured to electrically connect the electrical contact 232 to the electrical contact 233. Thus, referring to FIG. 9C and FIG. 10 together, the electronic device 29 disposed on the surface 204 and the electronic device 27 disposed on the surface 203 may be electrically connected to the interconnection layer 230 of the circuit layer 23. Further, the interconnection layer 230 may be configured to electrically connect the electronic device 29 to the electronic device 27.

One aspect of the present disclosure provides a semiconductor device. The semiconductor device includes a body and an interconnection structure. The body has a first lateral surface and a second lateral surface connected to the first lateral surface at an angle. The interconnection structure is configured to make electrical connection between the semiconductor device and a first electronic component mounted to the first lateral surface of the body of the semiconductor device and to make electrical connection between the semiconductor device and a second electronic component mounted to the second lateral surface of the body of the semiconductor device.

Another aspect of the present disclosure provides a semiconductor device. The semiconductor device includes a body, an interconnection structure, a plurality of first electrical contacts, a plurality of second electrical contacts and a plurality of third electrical contacts. The body has a bottom surface, a first surface and a second surface. The interconnection structure is formed a part of the body. The first electrical contacts are arranged on the bottom surface of the body and electrically connected to the interconnection structure. The second electrical contacts are arranged on the first surface of the body and electrically connected to the interconnection structure. The third electrical contacts are arranged on the second surface of the body and electrically connected to the interconnection structure.

Another aspect of the present disclosure provides a semiconductor interposer device. The semiconductor interposer device includes a first circuit layer and a second circuit layer. The first circuit layer has a plurality of first electrical contact on a first lateral surface of the semiconductor interposer device and a plurality of second electrical contacts on a second lateral surface of the semiconductor interposer device. The second circuit layer has a plurality of third electrical contacts on the first lateral surface of the semiconductor interposer device and a plurality of fourth electrical contacts on a third lateral surface of the semiconductor interposer device. The first electrical contact and the second electrical contact are electrically connected to each other and the third electrical contact and the fourth electrical contact are electrically connected to each other.

In the semiconductor interposer device, with the design of the interconnection structure and the electrical contact at the lateral side of the semiconductor interposer device can make electrical connection between the semiconductor interposer device and an electronic component mounted on the lateral side of the semiconductor interposer device.

Although the present disclosure and its advantages have been described in detail, it should be understood that various changes, substitutions and alterations can be made herein without departing from the spirit and scope of the disclosure as defined by the appended claims. For example, many of the processes discussed can be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device, comprising:
a body having a first lateral surface and a second lateral surface angled relative to the first lateral surface; and
an interconnection structure;
wherein the interconnection structure is configured to make electrical connection between the semiconductor device and a first electronic component mounted to the first lateral surface of the body of the semiconductor device and to make electrical connection between the semiconductor device and a second electronic component mounted to the second lateral surface of the body of the semiconductor device.

2. The semiconductor device of claim 1, wherein the body has a third lateral surface opposite to the first lateral surface, and wherein the interconnection structure is configured to make electrical connection between the semiconductor device and a third electronic component mounted to the third lateral surface of the body of the semiconductor device.

3. The semiconductor device of claim 1, wherein the body has a fourth lateral surface opposite to the second lateral surface, and wherein the interconnection structure is configured to make electrical connection between the semiconductor device and a fourth electronic component mounted to the fourth lateral surface of the body of the semiconductor device.

4. The semiconductor device of claim 1, wherein the interconnection structure is configured to electrically connect the first electronic component to the second electronic component.

5. The semiconductor device of claim 2, wherein the interconnection structure is configured to electrically connect the first electronic component to the third electronic component.

6. The semiconductor device of claim 2, wherein the interconnection structure is configured to electrically connect the second electronic component to the third electronic component.

7. The semiconductor device of claim 3, wherein the interconnection structure is configured to electrically connect the first electronic component to the fourth electronic component.

8. The semiconductor device of claim 1, wherein an angle between the first surface of the body and the second surface is around 90 degrees.

9. A semiconductor device, comprising:
a body having a bottom surface, a first surface and a second surface;
an interconnection structure formed a part of the body;
a plurality of first electrical contacts at the bottom surface of the body and electrically connected to the interconnection structure;
a plurality of second electrical contacts at the first surface of the body and electrically connected to the interconnection structure; and
a plurality of third electrical contacts at the second surface of the body and electrically connected to the interconnection structure.

10. The semiconductor device of claim 9, wherein the first surface is connected to the bottom surface and the second surface is opposite to the bottom surface.

11. The semiconductor device of claim 9, wherein the first surface is connected to the bottom surface and the second surface is opposite to the first surface.

12. The semiconductor device of claim 10, wherein the body has a third surface opposite to the first surface, and wherein a plurality of fourth electrical contacts at the third surface and electrically connected to the interconnection structure.

13. The semiconductor device of claim 9, wherein the interconnection structure comprises a first redistribution layer and a second redistribution layer, and wherein the first electrical contact is electrically connected to the second electrical contact through the first redistribution layer, and wherein the first electrical contact is electrically connected to the third electrical contact through the second redistribution layer.

14. The semiconductor device of claim 12, wherein the interconnection structure comprises a third redistribution layer, and wherein the first electrical contact is electrically connected to the third electrical contact through the third redistribution layer, and wherein the fourth electrical contact is electrically connected to the third electrical contact through the third redistribution layer.

15. The semiconductor device of claim 13, wherein the first electrical contact is configured to electrically connected to a first electronic component, the second electrical contact is configured to electrically connected to a second electronic component and the third electrical contact is configured to electrically connected to a third electronic component, and wherein the first redistribution layer is configured to electrically connect the first electronic component to the second electronic component and the second redistribution layer is configured to electrically connect the first electronic component to the third electronic component.

16. The semiconductor device of claim 15, wherein the first electronic component comprises a first substrate.

17. The semiconductor device of claim 15, wherein the second surface is opposite to the bottom surface, and wherein the third electronic component comprises a second substrate.

18. The semiconductor device of claim 14, wherein the first electrical contact is configured to electrically connected to a fourth electronic component, the third electrical contact is configured to electrically connected to a fifth electronic component and the fourth electrical contact is configured to electrically connected to a sixth electronic component, and wherein the third redistribution layer is configured to electrically connect the fourth electronic component to the fifth electronic component and to electrically connect the fifth electronic component to the sixth electronic component.

19. The semiconductor device of claim 18, wherein the fourth electronic component comprises a third substrate.

20. The semiconductor device of claim 19, wherein the fifth electronic component comprises a fourth substrate.
